(19) United States
(12) Patent Application Publication
(10) Pub. No.: US 2007/0131945 A1
(43) Pub. Date: Jun. 14, 2007

(54) Light-emitting semiconductor device with open-bypass function

(75) Inventors: Rong-Tsung Lin, Hsin-chu City (TW); Hsing-Fu Liu, Hsin-chu City (TW)

Correspondence Address: CROCKETT & CROCKETT, 24012 CALLE DE LA PLATA, SUITE 400, LAGUNA HILLS, CA, 92653, US

(73) Assignee: Macroblock, Inc.

(21) Appl. No.: 11/447,588

(22) Filed: Jun. 5, 2006

(30) Foreign Application Priority Data
Dec. 13, 2005 (TW) 94144011

(51) Int. Cl. H01L 33/00

(52) U.S. Cl. 257/81

(57) ABSTRACT

This invention discloses a light-emitting semiconductor device with open-bypass function, which comprises two terminals providing a current, at least one LED unit and a bypass switch. Electrodes of the LED unit and the bypass switch are properly connected to the terminals, so that the bypass switch will provide an alternative path for current flowing through if the circuit of the LEDs unit between two terminals is open.

This application claims priority to Taiwan Patent Application 094144011 filed Dec. 13, 2005.

### BACKGROUND OF THE INVENTION

1. Field of the Invention

This invention relates to a light-emitting semiconductor device with open-bypass function.

2. Related Prior Art

For serial or parallel LEDs, an open or short circuit may make the LED inoperable so that it cannot be lit to be lit. The open circuit results in failure all LEDs serially connected to this circuit; and the short circuit causes one or more LEDs to be “omitted”.

Therefore, this invention provides a bypass switch in the LED circuit.

### SUMMARY OF THE INVENTION

The light-emitting semiconductor device with an open-bypass function comprises a first terminal, a second terminal, at least one LED unit and a bypass switch. Each LED unit composed of one or more LED die has a first electrode and a second electrode respectively connected to the first terminal and the second terminal. The bypass switch also has a first electrode and a second electrode (referred to as the third and fourth electrodes in the claims) respectively connected to the first terminal and the second terminal of the light-emitting semiconductor device.

In a normal condition, a current applied to the first and the second terminals can be conducted through the LED unit for lighting it, and the switch is in an “Off” state without current flowing through. If the circuit of the LED unit between two terminals is open and the current cannot be conducted through, the bypass switch will be in an “On” state for conducting the current.

Accordingly, the first and the second terminals of the light-emitting semiconductor device can be always electrically conductive.

This invention also comprises a series or parallel circuit comprising several devices and a current source.

### BRIEF DESCRIPTION OF THE DRAWINGS

FIG. 1 shows the light-emitting semiconductor device of this invention.

FIGS. 2 and 3 respectively show the LED unit and the bypass switch.

FIGS. 4 and 5 respectively show the current flow when the switch is in the “On” and “Off” states.

FIG. 6 shows the electrical connection of this invention

FIGS. 7 and 8 respectively show the series and the parallel circuits.

### DETAILED DESCRIPTION OF THE PREFERRED EMBODIMENTS

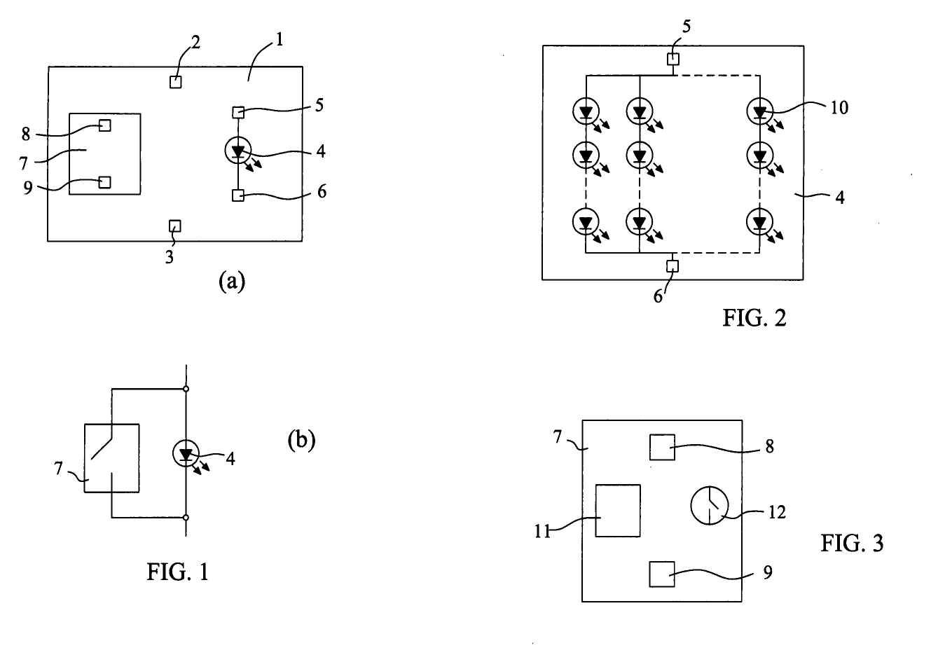

FIG. 1(a) shows a light-emitting semiconductor device 1 comprising two terminals defined as a first terminal 2 and a second terminal 3, an LED unit 4 and a switch 7 for bypassing. The LED unit 4 includes several LED dice 10 as shown in FIG. 2, and has a first electrode 5 and a second electrode 6 respectively connected to the first terminal 2 and the second terminal 3. In a normal condition, the circuit involving the LED unit 4 is electrically connected and the LED dice can be lit by applying a current to the terminals 2 and 3. However, if the circuit is open, the LED unit 4 cannot be lit.

The switch 7 is made with an integrated circuit and also has a first electrode 8 and a second electrode 9 respectively connected to the terminals 2 and 3. The switch 7 includes a voltage detection circuit 11 and a switch circuit 12, as shown in FIG. 3. The switch 7 is electrically open and in an “Off” state, but closed and in an “On” state when triggered by a first signal received from the electrodes 8 and 9. This first signal is a voltage equal to or higher than a predetermined value and generated when the circuit involving the LED unit 4 is open.

FIG. 1(b) shows the LED unit 4 connected to the switch 7 through a common contact and thus controlled by the switch 7.

The voltage detection circuit 11 has an anode, a cathode and a gate, wherein the anode and the cathode are respectively connected to the electrodes 8 and 9. The switch circuit 12 also has an anode, a cathode and a gate, wherein the anode and the cathode are also respectively connected to the electrodes 8 and 9. The gates of the circuits 11 and 12 are connected to each other. By detecting voltage of the circuit, the circuit 11 can generate a second signal to drive the gate of the switch circuit 12 through the gate of the voltage detection circuit 11. Then the switch circuit 12 enters into the “On” state.

In this invention, the switch circuit can be designed as follows:
(1) One PNPN thyristor having a P anode and an N cathode respectively connected to the anode and cathode of the switch circuit.
(2) Two bipolar junction transistors

The first bipolar junction transistor has a first emitter, a first base and a first collector; the second bipolar junction transistor has a second emitter, a second base and a second collector. The first emitter and the second emitter are respectively connected to the anode and the cathode of the switch circuit. The first base is connected to the second collector. The first collector is connected to the second base.
(3) Two MOSFETs

The first MOSFET has a first source, a first gate and a first drain; the second MOSFET has a second source, a second gate and a second drain. The first source and the second source are respectively connected to the anode and the cathode of the switch circuit. The first gate is connected to the second drain. The first drain is connected to the second gate.
(4) One bipolar junction transistor and one MOSFET

The bipolar junction transistor has an emitter, a base and a collector; the MOSFET has a source, a gate and a drain. The emitter and the source are respectively connected to the anode (or the cathode) and the cathode (or the anode) of the switch circuit. The base is connected to the drain. The collector is connected to the gate.

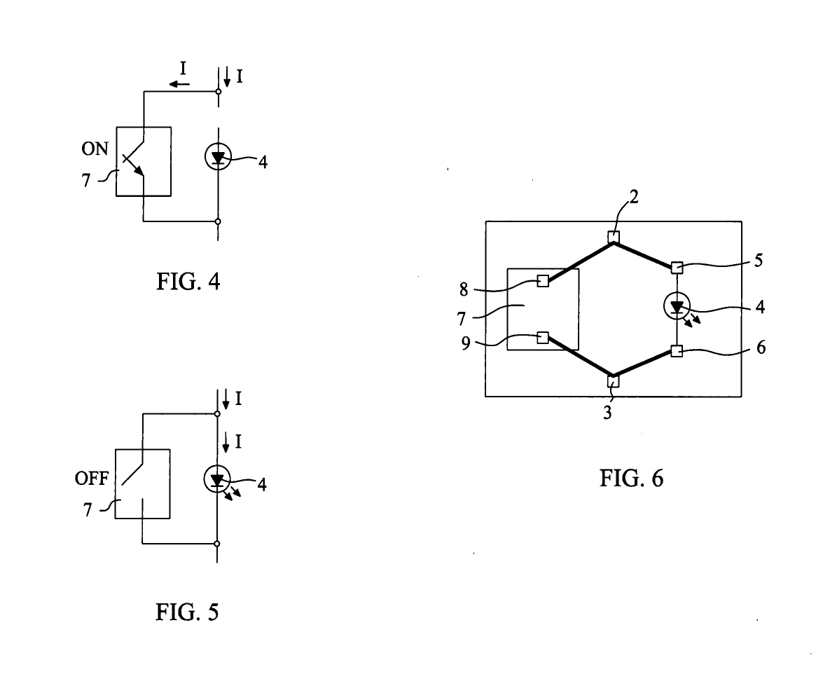

The light-emitting semiconductor device 1 is operated as follows:
(1) If electrical connection of the LED unit 4 is abnormally open, the current can not be conducted through the LED unit 4; and the switch 7 will be in the “On” state and enable the current to flow through, as shown in FIG. 4.
(2) If electrical connection of the LED unit 4 is normal, a current can be conducted through the LED unit 4 for lighting it; and the switch 7 is in the “Off” state without current flowing through, as shown in FIG. 5.

FIG. 6 shows the electrical connection of the device. The electrode 5 of the LED unit 4 and the electrode 8 of the switch 7 are commonly connected to the first terminal 2 of the device 1. The electrode 6 of the LED unit 4 and the electrode 9 of the switch 7 are commonly connected to the second terminal 3 of the device 1.

The terminals of the light-emitting semiconductor device can be attached to a substrate by wire bonding and surface mount technology.

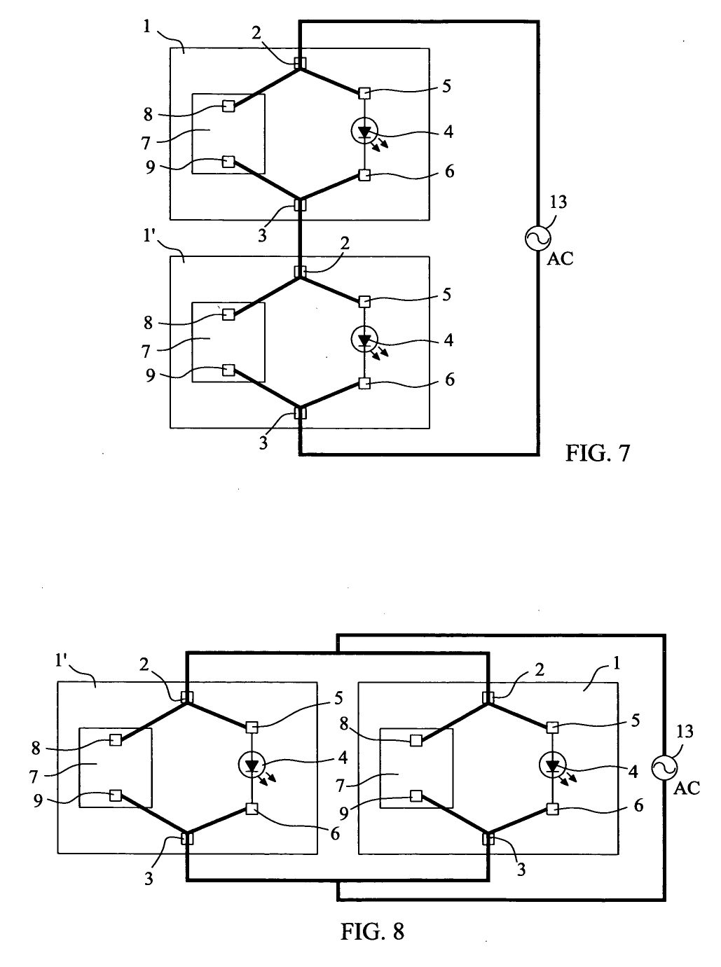

FIG. 7 shows a series circuit. The terminal 3 of the device 1 is connected to the terminal 2′ of the device 1′; and the terminal 2 of the device 1 and the terminal 3′ of the device 1′ are individually connected to a current source 13. FIG. 8 shows a parallel circuit. The terminal 2 of the device 1 and the terminal 2′ of the device 1′ are commonly connected to a current source; and the terminal 3 of the device 1 and the terminal 3′ of the device 1′ are commonly connected to the current source. That is, the devices and the current source can form a series or parallel circuit always conductive by providing the bypass switch.

What is claimed is:

1. A light-emitting semiconductor device with open-bypass function, comprising:
a first terminal;
a second terminal;
at least one LED unit each comprising one or more LED die, a first electrode and a second electrode respectively connected to the first and the second terminals; and
a bypass switch comprising a third electrode and a fourth electrode respectively connected to the first and the second terminals;
wherein
the bypass switch will be in an “Off” state without current flowing through if the LED unit can be lit by applying a current to the first and second terminals; or
the bypass switch will be in an “On” state for conducting the current if the LED unit is in an open circuit.

2. The light-emitting semiconductor device of claim 1, wherein the first and the second terminals are attached to a substrate by wire bonding and surface mount technology.

3. The light-emitting semiconductor device of claim 1, wherein the LED unit will generate a first signal delivered to the third electrode and a fourth of the bypass switch as being in an open circuit; and
the bypass switch will be in the “Off” state if the first signal is lower than a predetermined voltage; or
the bypass switch will be triggered to enter into the “On” state if the first signal is equal to or higher than the predetermined voltage.

4. The light-emitting semiconductor device of claim 1, wherein the bypass switch is formed as an integrated circuit and comprises:
a voltage detection circuit with an anode, a cathode and a gate, wherein the anode and the cathode are respectively connected to the third electrode and a fourth of the bypass switch; and
a switch circuit with an anode, a cathode and a gate, wherein the anode and the cathode are respectively connected to the third electrode and a fourth of the bypass switch, and the gate is connected to the gate of the voltage detection circuit;
wherein the voltage detection circuit can generate a second signal according to the detected voltage, and the second signal will drive the gate of the switch circuit through the gate of the voltage detection circuit and therefore turn on the switch circuit into the “On” state.

5. The light-emitting semiconductor device of claim 4, wherein the switch circuit comprises a PNPN thyristor with a P anode and an N cathode respectively connected to the anode and the cathode of the switch circuit.

6. The light-emitting semiconductor device of claim 4, wherein the switch circuit comprises a first bipolar junction transistor with a first emitter, a first base and a first collector and a second bipolar junction transistor with a second emitter, a second base and a second collector; wherein:
the first emitter and the second emitter are respectively connected to the anode and the cathode of the switch circuit;
the first base is connected to the second collector; and
the first collector is connected to the second base.

7. The light-emitting semiconductor device of claim 4, wherein the switch circuit comprises a first MOSFET with a first source, a first gate and a first drain and a second MOSFET with a second source, a second gate and a second drain; wherein:
the first source and the second source are respectively connected to the anode and the cathode of the switch circuit;
the first gate is connected to the second drain; and
the first drain is connected to the second gate.

8. The light-emitting semiconductor device of claim 4, wherein the switch circuit comprises a bipolar junction transistor with an emitter, a base and a collector and a MOSFET with a source, a gate and a drain; wherein:
the emitter or the source is connected to the anode or the cathode of the switch circuit;
the base is connected to the drain;
the collector is connected to the gate.

9. A light-emitting semiconductor apparatus, comprising a plurality of the light-emitting semiconductor devices of claim I and a current source to construct a series or parallel circuit.
